(19) United States
(12) Patent Application Publication
(10) Pub. No.: US 2025/0018920 A1
(43) Pub. Date: Jan. 16, 2025

(54) SYSTEM FOR DETERMINING REMAINING LIFE OF AT LEAST ONE COMPONENT ARRANGED TO BE INSTALLED ON A VEHICLE, AND BRAKING SYSTEM

(71) Applicant: Faiveley Transport Italia S.P.A., Piossasco (Torino) (IT)

(72) Inventor: Matteo Frea, Cantalupa (Torino) (IT)

(73) Assignee: Faiveley Transport Italia S.P.A., Piossasco (Torino) (IT)

(21) Appl. No.: 18/713,347

(22) PCT Filed: Nov. 24, 2022
(86) PCT No.: PCT/IB2022/061374

§ 371 Date: May 24, 2024

(30) Foreign Application Priority Data
Nov. 24, 2021 (IT) 102021000029702

(51) Int. Cl. B60T 17/22; B60T 8/17; B61D 41/00; G01R 19/165; G07C 5/08

(52) U.S. Cl. CPC B60T 17/228; B60T 8/1705; B61D 41/00; G01R 19/16576; G07C 5/0808; G07C 5/085; B60T 2240/00; B60T 2250/00; B60T 2250/04

(57) ABSTRACT

A system is described for determining remaining life of at least one component arranged to be installed on a vehicle, particularly a railway vehicle, comprising a control means arranged for measuring, from when the at least one component has been installed in the vehicle, a usage data of the at least one component; receiving or including predetermined end-of-life data indicative of the expected end-of-life of the component; and determining a remaining life value of the component based on the difference between the predetermined end-of-life data and the measured usage data.

### TECHNICAL FIELD

The present invention is generally in the field of vehicles; in particular, the invention relates to a system for determining remaining life of at least one component arranged to be installed on a vehicle, particularly a railway vehicle, and a braking system.

### PRIOR ART

Components installed in a vehicle are subject to wear caused by the performance of the operations for which they were designed.

Therefore, it is essential for the vehicle manufacturer/operator to be able to monitor the actual status of wear of the components installed in the vehicle. This monitoring is particularly important for components that perform functions that may impact the overall safety of the vehicle, e.g., components required for the traction/braking management of the vehicle.

In the prior art, solutions exist that are able to verify the proper operation of a device based on a comparison of one of their operating parameters with the operating parameters of other similar components installed in the vehicle. Specifically, these solutions are arranged to signal that the component is no longer working properly and is to be replaced when the operating parameter of this component differs, at least by a predetermined threshold, from the value of the operating parameters of the other similar components in the vehicle.

Disadvantageously, these solutions are unable to determine the true state of wear of the device. For example, a component nearing the end of life could still provide an operating parameter that is in line with the operating parameters of the additional similar components in the vehicle, possibly also nearing the end of life. In this case, although the component is nearing the end of life, these solutions would still evaluate it as still functioning, on a par with a new component.

### SUMMARY OF THE INVENTION

One object of the present invention is therefore to provide a solution for monitoring the actual status of wear of at least one component installed in the vehicle.

A further object is to provide a solution that may improve the planning of any maintenance to be implemented for a vehicle.

The aforesaid and other objects and advantages are achieved, according to one aspect of the invention, by a system for determining remaining life of at least one component arranged to be installed on a vehicle, particularly a railway vehicle, having the features defined in claim 1, and by a braking system having the features defined in claim 31. Preferred embodiments of the invention are defined in the dependent claims, the content of which is to be understood as an integral part of the present description.

### BRIEF DESCRIPTION OF THE DRAWINGS

The functional and structural features of some preferred embodiments of a system for determining remaining life of at least one component arranged to be installed on a vehicle, particularly a railway vehicle, and a braking system according to the invention will now be described. Reference is made to the accompanying drawings, in which:

FIG. 1 illustrates a first embodiment of a system for determining remaining life of at least one component according to the invention;

FIG. 2 illustrates an embodiment of a system for determining remaining life of at least one component including a communication means;

FIG. 3 illustrates an embodiment of a system for determining remaining life of at least one component including a storage means;

FIG. 4 illustrates an embodiment of a system for determining remaining life of at least one component including an activation preventing means; and

FIG. 5 illustrates an embodiment of a braking system according to the present invention.

### DETAILED DESCRIPTION

Before explaining in detail a plurality of embodiments of the invention, it should be clarified that the invention is not limited in its application to the design details and configuration of the components presented in the following description or illustrated in the drawings. The invention may assume other embodiments and be implemented or constructed in practice in different ways. It should also be understood that the phraseology and terminology have a descriptive purpose and should not be construed as limiting. The use of “include” and “comprise” and the variations thereof are intended to cover the elements set out below and their equivalents, as well as additional elements and the equivalents thereof.

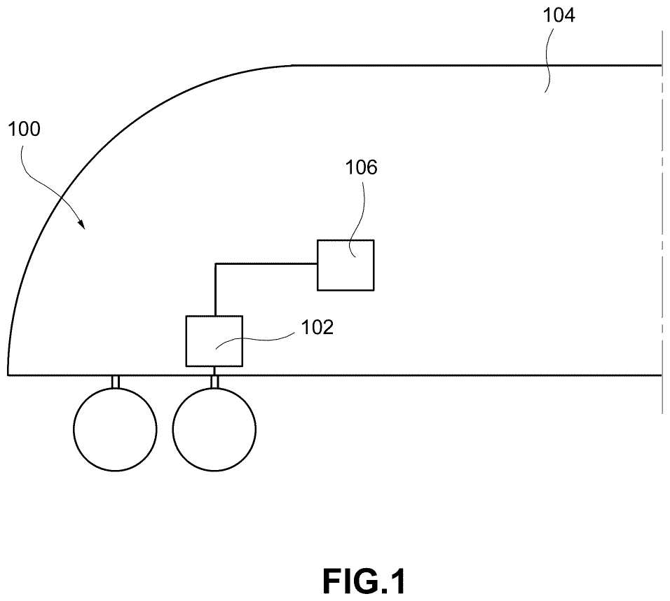

Referring initially to FIG. 1, in a first embodiment, a system 100 for determining remaining life of at least one component 102 arranged to be installed on a vehicle 104, particularly a railway vehicle, comprises a control means 106 arranged for measuring, from when said at least one component has been installed in the vehicle, a usage data of said at least one component.

For example, the usage data may be an indicative value of the usage of that component. Moreover, “measuring this data” may mean either a direct measurement of the data (e.g., a direct measurement of the value of the data) or an indirect measurement of the data, i.e., the determination of the value of that data from a measurement of an additional/parameter value.

In other words, the control means, by measuring/determining the usage data of a component, is able to monitor the usage of that component from the time it was installed in the vehicle.

Preferably, the usage data may be indicative of the number of activations of the at least one component or indicative of the activation time of the at least one component.

In other words, the component usage data may be representative data of the actual usage of the component.

The control means 106 is also arranged to receive or include predetermined end-of-life data indicative of the expected end-of-life of the component.

Additionally, the control means is arranged to determine a remaining life value of the component based on the difference between the predetermined end-of-life data and said measured usage data.

Preferably, the usage data arranged to be measured by the control means may be a fluid volume data that has been received or generated by said at least one component 102 from when the at least one component 102 was installed in the vehicle 104.

For example, the at least one component may be a valve, and the fluid volume data may be a value indicative of the fluid that was received at the valve inlet or it may be a value indicative of the fluid that was supplied at the valve outlet. In other words, the fluid volume data will be indicative of the amount of fluid that has been handled by the valve from when it was installed in the vehicle 104.

For example, the fluid may be a fluid present in a main line or a brake line/brake pipe of a vehicle or a fluid present in an auxiliary reservoir intended to accumulate compressed air to generate braking air. The valve may be, for example, one that receives fluid directly from the brake line, or from the auxiliary reservoir, and adjusts the output for its delivery to a brake cylinder of the vehicle.

Preferably, for measuring the fluid volume data, the control means may comprise or be associated with a fluid measurement means arranged to be coupled to a fluid inlet port of the at least one component 102 and to measure the volume of fluid that was received by said at least one component 102. Or, for measuring fluid volume data, the control means may comprise or be associated with a fluid measurement means arranged to be coupled to a fluid outlet port of the at least one component 102 and to measure the volume of fluid that was generated by said at least one component 102.

In one alternative, the fluid volume may be determined from a fluid pressure value measured by at least one pressure transducer arranged downstream and/or upstream of the component.

For example, the fluid measurement means may comprise or be at least one pressure transducer or flow sensor that is arranged to measure the flow rate of a fluid, i.e., the volume of fluid passing through a section in a unit of time.

Preferably, the control means may be or include at least one among a microprocessor, processor, microcontroller, controller, PLC, FPGA, control unit, control system or control device, or the like.

Preferably, the predetermined end-of-life data may be arranged to be derived from at least one of:
a data sheet provided by a manufacturer of the component;
an experience return, REX, provided by a manufacturer of the component or vehicle, or by an integrator of a system that includes said component;
a component life duration verification test performed by the manufacturer of the vehicle or the component, or by the integrator of the system that includes said component;
an accelerated life test performed by the manufacturer of the vehicle or component, or by the integrator of the system that includes said component.

In a first practical example, the component may be a valve, and the usage data may be indicative of the number of activations of said valve. In such a case, preferably, for measuring the data indicative of the number of activations, the control means may comprise or be associated with an activation measuring means.

For example, the activation measuring means may be associated with an activation circuit of the valve. For example, the activation measuring means may comprise or be a counter that is arranged to count the number of activations.

In a second practical example, the component may be a compressor, and the usage data may be indicative of the total time in which said compressor was activated. In such a case, preferably, for measuring the data indicative of the total time in which said compressor was activated, the control means may comprise or be associated with a time measuring means. For example, the activation measuring means may be associated with an activation circuit of the compressor. For example, the time measuring means may comprise or be a timer or a stopwatch.

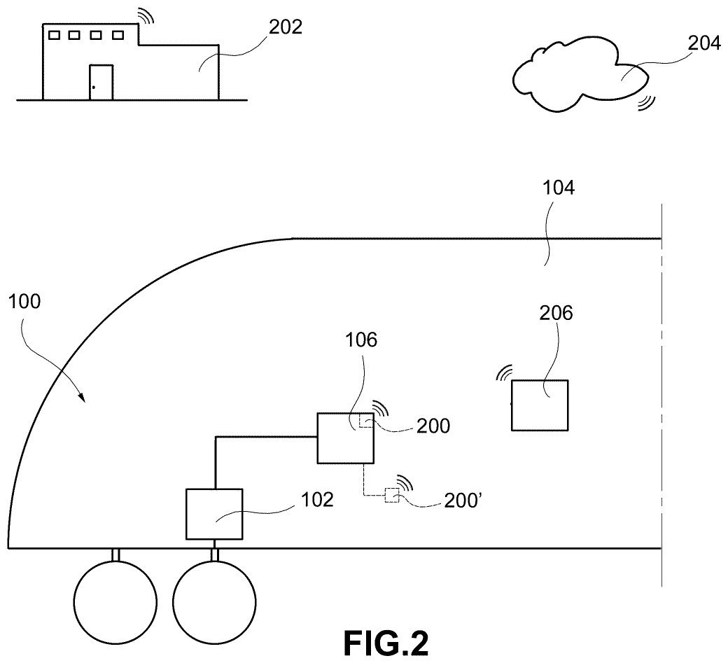

Preferably, as shown in FIG. 2, the control means 106 may include a communication means 200 or may be arranged to be associated with a communication means 200′.

Preferably, the communication means may be a wired and/or a wireless communication means. For example, the communication means may be a wired line or a wireless network, Bluetooth, or other wireless technology.

Preferably, the control means may be arranged, via the communication means, to transmit the measured usage data and/or the determined remaining life value to at least one among:
a ground station 202;
a cloud 204;
an additional control unit 206 on-board the vehicle.

By transmitting the usage data to one of the above parties, the scheduling of the maintenance activities associated with the component or vehicle may be easily planned by those parties.

Preferably, the control means may be arranged to receive, via the communication means, the predetermined end-of-life data from a database including one or more predetermined end-of-life data. Each end-of-life data included in the data-base may be associated with a particular component.

In this way, depending on the type of component being controlled, each control means will be able to receive the correct end-of-life data for that type of component. For example, the database may be a database installed locally in the vehicle or a remote database that transmits via wireless communication to the various control means of the vehicle.

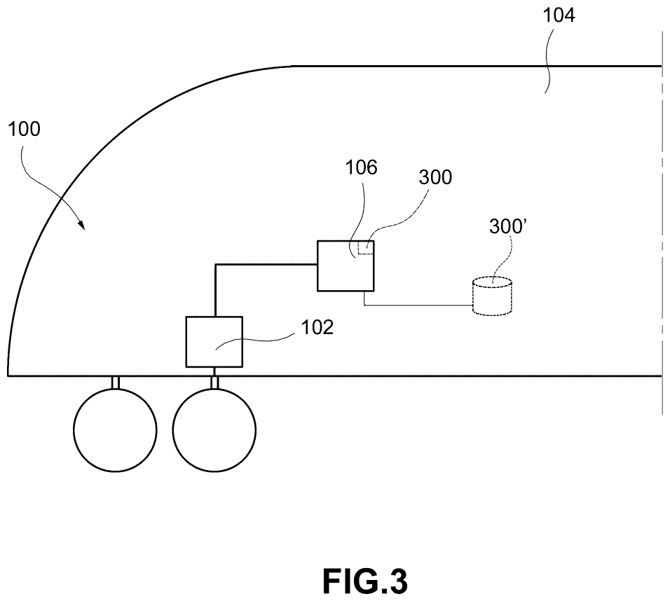

Preferably, as observable in FIG. 3, the control means may include storage means 300 or may be arranged to be associated with a storage means 300′.

Preferably, the storage means may be arranged to contain the predetermined end-of-life data.

Preferably, the control means may be arranged to store the measured usage data in said storage means.

Preferably, the control means may be arranged to update the value of the usage data stored in the storage means each time the vehicle is turned off, and/or according to a predetermined periodicity, and/or upon the occurrence of at least one predetermined event.

For example, the storage means may be a memory unit, e.g., a nonvolatile memory unit, i.e., one that is capable of retaining information in memory even in the absence of power. Examples of nonvolatile memory units may be nonvolatile ROM and RAM memories, flash memories, a large part of magnetic memory units, etc.

Preferably, the system for determining remaining life of at least one component according to the claim may comprise a voltage measuring means arranged to measure a voltage value of an electrical power line connected to a battery of the vehicle. The control means, in such a case, may be arranged to determine that the vehicle is turned off when the measured voltage value is below a predetermined voltage threshold.

Alternatively or additionally, the system for determining remaining life of at least one component according to the claim may comprise a current measuring means arranged to measure a current value of the electrical power line connected to a battery of the vehicle. In such a case, the control means may be arranged to determine that the vehicle is turned off when the measured current value is below a predetermined current threshold.

A person skilled in the art could also consider measuring a current value and, through normal calculations, e.g., according to Ohm's law, deriving a voltage value to compare with a predetermined voltage threshold. The same may be similarly applied in reverse starting with a voltage measurement.

Preferably, the system for determining remaining life of at least one component may comprise a pressure measuring means arranged to measure a pressure value of a fluid flowing in a brake pipe of the vehicle. The control means may be arranged to determine that the vehicle is turned off when the measured pressure value is below a predetermined pressure threshold.

Preferably, the brake pipe may be arranged to contain a fluid. For example, the fluid may be compressed air and may be used by a vehicle braking system to propagate a braking force to slow the vehicle. The braking force value generated is dependent on the pressure value of the fluid in the brake pipe.

Preferably, the control means may be arranged to update the usage data stored in the storage means when it determines that the vehicle has arrived at a certain destination.

For example, the destination may be set by a driver/machine operator of the vehicle or be received by the control means from a remote control station.

In such a case, the system for determining remaining life of at least one component may comprise a localization means arranged to detect the position of the vehicle along a route. The control means may be arranged to determine that the vehicle has arrived at its destination when the detected position coincides with a specified target position.

Preferably, the aforementioned at least one predetermined event, at which the usage data may be stored in the storage means, is a stop of the vehicle. The system for determining remaining life of at least one component may comprise a speed sensor means.

The speed sensor means may be arranged to measure a linear speed of travel of the vehicle, and the control means may be arranged to determine that a stop of the vehicle has occurred when the linear speed of travel is zero.

Or, the speed sensor means may be arranged to measure an angular velocity of a wheel or axle of the vehicle, and the control means may be arranged to determine that a stop of the vehicle has occurred when the value of angular velocity is zero.

In a further aspect, the control means may be arranged to read the usage data stored in the storage means each time the vehicle is turned on. In this way, monitoring of the usage of the component may be resumed, on each trip, from the last measured and stored usage data.

Preferably, the system for determining remaining life of at least one component may again comprise the voltage measuring means arranged to measure a voltage value of an electrical power line connected to a battery of the vehicle. In such a case, the control means is arranged to determine that the vehicle is turned on when the measured voltage value is above a predetermined voltage threshold.

Alternatively or additionally, the system for determining remaining life of at least one component may again comprise the current measuring means arranged to measure a current value of an electrical power line connected to a battery of the vehicle. In such a case, the control means may be arranged to determine that the vehicle is turned on when the measured current value is greater than a predetermined current threshold.

As already discussed above, also in this case a person skilled in the art could also measure a current value and, through normal calculations, e.g. according to Ohm's law, derive a voltage value to compare with a predetermined voltage threshold. The same may similarly apply in reverse starting from a voltage measurement.

Preferably, the system for determining remaining life of at least one component may again comprise the pressure measuring means arranged to measure a pressure value of a fluid flowing in the brake pipe of the vehicle. In such a case, the control means may be arranged to determine that the vehicle is turned on when the measured pressure value is above a predetermined pressure threshold.

What was described above for storing, updating and reading the usage data in/from the storage means may find similar application in storing, updating and reading the determined remaining life value.

Preferably, when the determined remaining life value is below a first predetermined threshold, the control means may be arranged to determine that the component has reached a first level of wear. In such a case, when the control means determines that the component has reached the first level of wear, the control means may be arranged to generate a first alarm signal.

Preferably, when the remaining life value determined is less than a second predetermined threshold lower than said first predetermined threshold, the control means may be arranged to determine that the component has reached a second level of wear greater than the first level of wear. In such a case, when the control means determines that the component has reached the second level of wear, the control means may be arranged to generate a second alarm signal.

Having one or more wear thresholds makes it possible to monitor at various times the approaching end of the component's life. For example, the first threshold may be set at half of the component's useful life, and the second threshold may be set at ¾ of the component's useful life.

Preferably, when the determined remaining life value is zero, the control means may be arranged to determine that the component has reached the end of life. In such a case, when the control means determines that the component has reached the end of life, the control means may be arranged to generate an end-of-life signal.

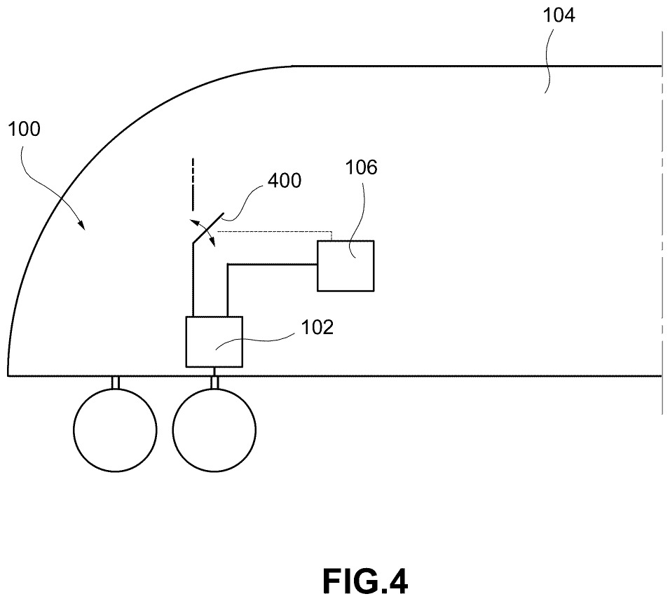

Preferably, as observable in FIG. 4, the system for determining remaining life of at least one component may comprise an activation preventing means 400 arranged to selectively assume a first state adapted to allow activation of said at least one component and a second state adapted to prevent the activation of said at least one component. In such a case, the control means may be arranged to bring or maintain the activation preventing means in its second state when it determines that the component has reached the end of life.

Preferably, the activation preventing means may be arranged to assume or maintain the second state when it receives said end-of-life signal from the control means.

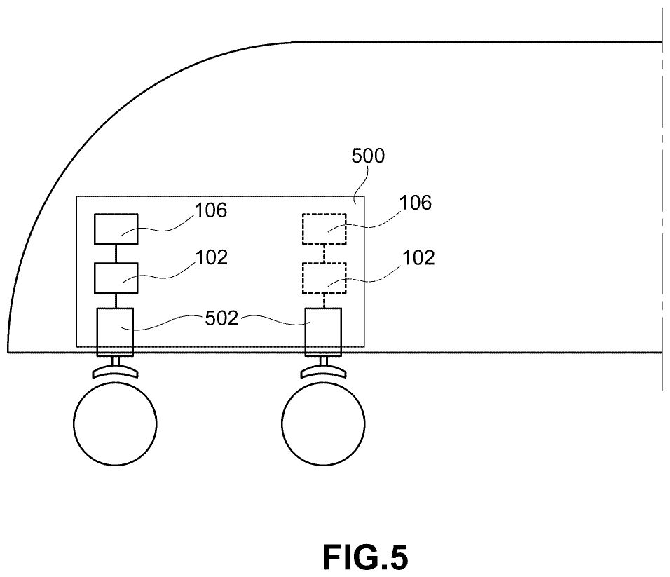

In a further aspect, as shown in FIG. 5, the present invention further relates to a braking system 500 for a vehicle. This braking system comprises:
braking means 502 arranged to generate a braking force suitable for slowing the vehicle;
at least one component arranged to be installed on the vehicle and whose activation is arranged to influence the braking force generated by the braking means; and
a system for determining remaining life of said at least one component according to any of the previously described embodiments.

Preferably, the control means may also be further arranged to control the braking means to adjust the braking force to slow the vehicle.

In other words, the control means may also be in charge of managing vehicle braking.

Preferably, the braking means may include or be an air brake, electropneumatic brake, electromechanical brake, electromagnetic brake, magnetic brake, friction brake, or any type of brake that may be used in a vehicle.

The advantage achieved is thus to have provided a solution that allows monitoring of the actual status of wear of at least one component installed in a vehicle and which allows for improved planning of any maintenance to be implemented for the vehicle.

As described above, the present invention is preferably applicable to at least one component installed on board a railway vehicle, traveling on track rails. For example, a vehicle as referred to herein may be a locomotive, and a course/route may include tracks on which the wheels of the locomotive roll. The embodiments described herein are not intended to be limited to vehicles on tracks. For example, the vehicle may be a car, a truck (for example a highway semi-trailer truck, a mining truck, a truck for transporting timber or the like), a motorcycle or the like, and the route may be a road or a trail.

Various aspects and embodiments of a system for determining remaining life of at least one component and braking system according to the invention have been described. It is understood that each embodiment may be combined with any other embodiment. Moreover, the invention is not limited to the embodiments described, but may be varied within the scope defined by the appended claims.

1. A system (100) for determining remaining life of at least one component (102) arranged to be installed on a vehicle (104), particularly a railway vehicle, comprising a control means (106) arranged for:
measuring, from when said at least one component (102) has been installed in the vehicle (104), a usage data of said at least one component (102);
receiving or including a predetermined end-of-life data, indicative of the expected end-of-life of the at least one component (102);
determining a remaining life value of the at least one component (102) based on the difference between the predetermined end-of-life data and said measured usage data.

2. The system for determining remaining life of at least one component of claim 1, wherein said predetermined end-of-life data is arranged to be derived from at least one of:
a data sheet provided by a manufacturer of the at least one component (102);
an experience return, REX, provided by the manufacturer of the at least one component (102) or manufacturer of the vehicle (104), or by an integrator of a system that includes the at least one component;
a component life duration verification test performed by the manufacturer of the vehicle (104) or the manufacturer of the at least one component (102), or by the integrator of the system that includes the at least one component; or
an accelerated life test performed by the manufacturer of the vehicle (104) or the manufacturer of the at least one component (102), or by the integrator of the system that includes the at least one component.

3. The system for determining remaining life of at least one component of claim 1, wherein said control means (106) includes a communication means (200) or is arranged to be associated with said communication means (200′).

4. The system for determining remaining life of at least one component according to claim 3, wherein the control means (106) is arranged to, via said communication means (200, 200′), transmit the measured usage data and/or the determined remaining life value to at least one of:
a ground station (202);
a cloud (204); or
an additional control unit (206) on-board the vehicle (104).

5. The system for determining remaining life of at least one component of claim 3, wherein said control means (106) is arranged to receive, via said communication means (200, 200′), the predetermined end-of-life data from a database including one or more predetermined end-of-life data;
each end-of-life data included in the database being associated with a respective component.

6. The system for determining remaining life of at least one component of claim 1, wherein said control means (106) includes a storage means (300) or is arranged to be associated with said storage means (300′).

7. The system for determining remaining life of at least one component of claim 6, wherein said storage means (300, 300′) is arranged to contain said predetermined end-of-life data.

8. The system for determining remaining life of at least one component of claim 6, wherein said control means (106) is arranged to store the measured usage data in said storage means (300, 300′).

9. The system for determining remaining life of at least one component according to of claim 8, wherein said control means (106) is arranged to update the usage data stored in said storage means (300, 300′):
each time the vehicle (104) is turned off;
according to a predetermined periodicity; or
upon the occurrence of at least one predetermined event.

10. The system for determining remaining life of at least one component of claim 9, comprising a voltage measuring means arranged to measure a voltage value of an electrical power line connected to a battery of the vehicle; wherein said control means is arranged to determine that the vehicle is turned off when the measured voltage value is below a predetermined voltage threshold.

11. The system for determining remaining life of at least one component of claim 9, comprising a pressure measuring means arranged to measure a pressure value of a fluid flowing in a brake pipe of the vehicle; wherein said control means is arranged to determine that the vehicle is turned off when the measured pressure value is below a predetermined pressure threshold.

12. The system for determining remaining life of at least one component of claim 9, wherein said control means is arranged to update the usage data stored in said storage means (300) when it determines that the vehicle has arrived at a destination.

13. The system for determining remaining life of at least one component of claim 12, comprising a localization means arranged to detect a position of the vehicle along a route; wherein said control means is arranged to determine that the vehicle has arrived at the destination when the detected position coincides with a specified target position.

14. The system for determining remaining life of the at least one component of claim 9, wherein said at least one predetermined event is a stop of the vehicle.

15. The system for determining remaining life of at least one component of claim 14, comprising a speed sensor means;
wherein said speed sensor means is arranged to measure a value of linear speed of travel of the vehicle, and said control means is arranged to determine that the stop of the vehicle has occurred when said value of linear speed of travel is zero.

16. The system for determining remaining life of at least one component of claim 8, wherein said control means (106) is arranged to read the usage data stored in said storage means (300) each time the vehicle is turned on.

17. The system for determining remaining life of at least one component of claim 16, comprising a voltage measuring means arranged to measure a voltage value of an electrical power line connected to a battery of the vehicle; wherein said control means is arranged to determine that the vehicle is turned on when the measured voltage value is above a predetermined voltage threshold.

18. The system for determining remaining life of at least one component according to claim 16, comprising a pressure measuring means arranged to measure a pressure value of a fluid flowing in a brake pipe of the vehicle; wherein said control means is arranged to determine that the vehicle is turned on when the measured pressure value is above a predetermined pressure threshold.

19. The system for determining remaining life of at least one component of claim 1, wherein, when the determined remaining life value is less than a first predetermined threshold, the control means (106) is arranged to determine that the component has reached a first level of wear.

20. The system for determining remaining life of at least one component of claim 19, wherein, when the control means (106) determines that the at least one component has reached the first level of wear, the control means is arranged to generate a first alarm signal.

21. The system for determining remaining life of at least one component of claim 19, wherein, when the determined remaining life value is less than a second predetermined threshold lower than said first predetermined threshold, the control means is arranged to determine that the component has reached a second wear level greater than the first wear level.

22. The system for determining remaining life of at least one component of claim 21, wherein, when the control means determines that the component has reached the second level of wear, the control means is arranged to generate a second alarm signal.

23. The system for determining remaining life of at least one component of claim 1, wherein, when the determined remaining life value is zero, the control means is arranged to determine that the component has reached an end of life.

24. The system for determining remaining life of at least one component according to claim 23, wherein, when the control means determines that the component has reached the end of life, the control means is arranged to generate an end-of-life signal.

25. The system for determining remaining life of at least one component of claim 1, wherein said usage data is indicative of the number of activations of said at least one component.

26. The system for determining remaining life of at least one component claim 1, wherein said usage data is indicative of an activation time of said at least one component (102).

27. The system for determining remaining life of at least one component of claim 24, comprising an activation preventing means (400) arranged to selectively assume a first state adapted to allow activation of said at least one component and a second state adapted to prevent activation of said at least one component;
wherein said control means (106) is arranged to bring or maintain said activation preventing means in its second state when it determines that the component has reached the end of life.

28. The system for determining remaining life of at least one component of claim 27, wherein said activation preventing means (400) is arranged to assume or maintain the second state when it receives said end-of-life signal from the control means.

29. The system for determining remaining life of at least one component of claim 1, wherein the usage data arranged to be measured by the control means is a fluid volume data that has been received or generated by said at least one component (102) from when said at least one component (102) was installed in the vehicle (104).

30. The system for determining remaining life of at least one component of claim 29, wherein the control means comprises or is associated with a fluid measuring means arranged to be coupled to a fluid inlet port of the at least one component (102) and to measure a volume of fluid that was received by said at least one component (102).

31. A braking system (500) for a vehicle, comprising:
a braking means (502) arranged to generate a braking force to slow the vehicle;
at least one component (102) arranged to be installed on the vehicle and whose activation is arranged to influence the braking force generated by the braking means (502); and
the system for determining remaining life of said at least one component of claim 1.

32. The braking system according to claim 31, wherein said control means (102) is further arranged to control said braking means (502) to adjust said braking force adapted to slow the vehicle (104).

33. The system for determining remaining life of at least one component of claim 9, comprising a current measuring means arranged to measure a current value of an electrical power line connected to a battery of the vehicle; wherein said control means is arranged to determine that the vehicle is turned off when the measured current value is below a predetermined current threshold.

34. The system for determining remaining life of at least one component of claim 14, comprising a speed sensor means;
wherein said speed sensor means is arranged to measure a value of angular velocity of a wheel of the vehicle, and said control means is arranged to determine that the stop of the vehicle has occurred when said value of angular velocity is zero.

35. The system for determining remaining life of at least one component of claim 16, comprising a current measuring means arranged to measure a current value of an electrical power line connected to a battery of the vehicle; wherein said control means is arranged to determine that the vehicle is turned on when the measured current value is greater than a predetermined current threshold.

36. The system for determining remaining life of at least one component of claim 29, wherein the control means comprises or is associated with a fluid measuring means arranged to be coupled to a fluid outlet port of the at least one component (102) and to measure a volume of fluid that was generated by said at least one component (102).
